(19) United States
(12) Patent Application Publication
(10) Pub. No.: US 2021/0321733 A1
(43) Pub. Date: Oct. 21, 2021

(54) CUSTOMIZABLE BAGS

(71) Applicant: JLZ, LANDEDA (FR)

(72) Inventor: Vivien MULLER, ESCH-SUR-ALZETTE (LU)

(73) Assignee: JLZ, LANDEDA (FR)

(21) Appl. No.: 17/272,145

(22) PCT Filed: Aug. 28, 2019
(86) PCT No.: PCT/EP2019/072910

§ 371 Date: Feb. 26, 2021

(30) Foreign Application Priority Data
Aug. 28, 2018 (FR) FR1870962
Oct. 18, 2018 (FR) FR1871206

(51) Int. Cl. A45C 13/04; G06F 30/10; A45C 13/08

(52) U.S. Cl. CPC A45C 13/04; B33Y 80/00; A45C 13/086; G06F 30/10

(57) ABSTRACT

The subject matter of the present invention concerns bags, such as carrier bags, in particular handbags, which can be personalized individually, involving the use of a rigid frame, their method of manufacture, as well as the various elements relating thereto, such as their packaging

The subject matter of the present invention concerns bags, such as carrier bags, in particular handbags, which can be personalized individually, involving the use of a rigid frame, their method of manufacture, as well as the various elements relating thereto, such as their packaging.

Carrier bags, especially handbags, usually contain often very personal items such as identity papers, mobile phones or even laptops, medicines to be taken regularly, beauty products, jewelry, etc. They are thus considered by their users as intimate possessions. However, these carrier bags, especially handbags, are often produced on a large scale, limiting their personalisation.

The state of the art reports a few examples of bags that can be industrialised on a large scale with means of personalisation. For example, FR978474 is characterised by the possibility of rapid bag transformation. Similarly, EP0414656 discloses interchangeable elements on the bag at the owner's discretion. EP2163169 also discloses handbags with interchangeable linings. US2016183649 discloses handbags that can be “customised” with replaceable and interchangeable elements.

However, throughout the prior art, the general shape of these bags cannot be configured by the user. The prior art content itself to graft and/or interchange elements on bags whose general shapes are already determined by the manufacturer. Indeed, the prior art considers that the user can, presumably according to his or her wishes, change the external appearance of the bag with prefabricated elements. The personalisation finally consists in a personalised combination by each user of prefabricated elements. Moreover, in reality, the user rarely changes on a regular basis the combination of the elements forming his/her bag. Moreover, in all cases, the user does not really have a way out of the possibilities offered by the manufacturer, especially with regard to the general shape of the bag.

The subject matter of the present invention distinguishes itself from this prior art by offering additional means for personalizing bags, in particular handbags, by providing the technical means for the user to obtain a general external shape of the bag which is the one he/she has determined. This general shape is obtained according to the present invention by means of a frame integrated into the bag. This frame can be personalised by the computer tool, which allows the implementation of modular manufacturing tools, such as 3D printing, and particularly laser sintering. By proposing new technical means, the present invention allows the user to participate actively in the manufacture of his bag, at least in its design, and thus obtain a bag that is personal to him or her.

### SUMMARY OF THE INVENTION

The subject matter of the present invention therefore concerns a carrier bag frame, such as a handbag, comprising:
at least one rigid basal part (B) of polygonal shape, and/or
at least one at least partly rigid side face (L), preferably fixedly and/or movably attached to the basal part (B), if any.

The subject matter of the present invention also concerns a method of laser manufacturing of a metal part for a carrier bag, such as a handbag, comprising the following steps:

(a) 3D computer design of said metal part;

(b) transferring the 3D data obtained in step (a) to a 3D laser manufacturing device;

(c) applying a laser from the device of step (b) to at least one metal, such as a metal powder; and (d) applying a laser from the device of step (b) to at least one metal, such as a metal powder; and

(d) recovery of the metal part thus obtained in step (c).

Furthermore, the subject matter of the present invention concerns a carrier bag, such as a handbag, comprising a frame as presently described.

Furthermore, the subject matter of the present invention concerns a carrier bag package, such as a handbag, intended to contain a carrier bag according to the present invention. In particular, the bag intended to contain a bag according to the present invention may comprise an indication, such as a trademark and/or a suitable shape, enabling its contents to be identified, i.e., the bag according to the present invention.

### Definitions

In the context of the present invention by “frame”, it is understood at least one rigid part intended to support and/or maintain the arrangement in the space of the carrier bag, such as a handbag. The frame may or may not be visible from outside the bag. The frame may or may not be visible from at least one of the useful pockets of the bag. In a particular embodiment, the frame is fully inserted into the bag and is not visible from the outside or from the inside (useful pocket) of the bag. In another embodiment, the frame can be used in technical areas similar to handbags, such as jewelry boxes, purses or wallets. The frame can be used on its own or with a garnishing.

In the context of the present invention, a “carrier bag” is understood to be a container, preferably made of at least one flexible material, comprising at least one rigid frame as defined above, said bag being designed on the one hand to contain the attributes of one or more persons, and on the other hand to allow its transport by at least one person. The carrier bag comprises a base, and at least one side face connected to the base. Preferably, said carrier bag, such as a handbag, comprises at least one external means of grasping, such as a shoulder strap, handle, hooking point, etc., allowing its user to grasp it and carry it with him/her. Preferably, the carrier bag is adapted to be positioned between the arm and a side flank of the user's body, preferably a handbag containing the user's personal attributes. The carrier bag, such as a handbag, can be made of any soft material useful for this purpose. Preferably, the materials are high-quality materials such as natural leather, cotton, velvet, wool, silk or cashmere.

In the context of the present invention, the term “handbag” is understood to mean a carrier bag as defined above for daily or occasional use, often containing very personal effects such as identity papers, cell phones, a coin purse, wallet, bank cards, jewelry, etc. the said personal effects being able to be intended for the current uses of the daily life.

In the context of the present invention by “basal part”, it is understood the basal part of the frame, which is integrated into the base of the carrier bag. The basal part of the framework is delimited by its ridges and surfaces. The thickness of the basal part (corresponding to the ridge if the thickness of the basal part is constant and homogeneous) is significantly less than the length of the latter. Typically, the thickness of the ridge is less than one tenth of the length of the ridge under consideration. The basal part of the framework can take any possible polygonal shape. Preferably, this polygonal shape comprises at least one corrugated surface, generally convex and/or twisted.

Preferably, the basal part of the frame merges with the basal part of a bag, that is to say the part on which the bag rests when it is placed during its normal use. It is often referred to as the “bottom of the bag” when it comes to a handbag because this basal part is coincident with or adjoins the bottom of the useful pocket of the handbag. So, in a handbag with a top opening, the basal part is the lowest surface facing the opening.

In the context of the present invention, the term “rigid” is understood to mean a material resistant to torsional and shearing forces and which does not or hardly bend (on a human scale). For example, a rigid material according to the present invention presents a Young's modulus greater than or equal to 1 GPa, preferably greater than or equal to 2 GPa, more preferably greater than or equal to 3 GPa, even more preferably greater than or equal to 5 GPa. Examples of rigid materials according to the present invention comprise metals or metal alloys including aluminum, silver, chromium, copper, tin, iron, magnesium, manganese, nickel, gold, palladium, lead, platinum, titanium, zinc, zirconium. For example, it can be steel, such as stainless steel, rolled copper, or alloys including titanium. Other examples of rigid materials according to the present invention comprise certain rigid plastics, composite materials, biomaterials, metal oxides, optionally ceramics or even metal carbides. For example, it can be alumina, chromium carbide, titanium carbide, titanate, barium titanate, carbon, glass fibers, carbon fibers, polyamides, polycarbonates, polystyrene (eg extruded) epoxy resin, wood, such as bamboo, mahogany, oak, maple, etc.

In the context of the present invention by “polygonal shape”, it is understood a shape having several angles, and therefore several sides.

In the context of the present invention, the term “side face” comprises a planar element adjacent to an edge delimiting the basal part of polygonal shape. In the context of the present invention, the lateral face can be attached directly to the basal part. The lateral face can be fixed or movably attached to the basal part. Generally speaking, a movable attachment allows at least two elements to be connected to each other while allowing them certain significant movements relative to each other. In general, a fixed attachment, on the contrary, locks the at least two elements and prevents them from any significant movement with respect to each other. The lateral face can be linked to the basal part by its arrangement in the bag, i.e., it is a flexible material, even elastic, which can form the link between the basal part and the lateral face. A side face can comprise a flexible and/or rigid material. In a particular embodiment, one or more side faces can consist of one or more flexible or even elastic materials. In the case of a side face made of a rigid material, said side face may comprise at least one axis of rotation inscribed in the plane of a surface in question. Thus, in a particular embodiment, a lateral face can comprise several facets (F) attached to each other in a mobile manner and giving the necessary flexibility to the lateral face as a whole to allow opening of the frame (and therefore of the bag according to the invention). Typically, one of the ways to achieve flexibility is to inscribe a Y in a triangular face so that the three ends of the Y correspond with the vertices of the triangle. The axes of rotation are then represented by the 3 branches of the Y connected to the vertices of the triangle. In a particular embodiment according to the invention, the facets (F) are of any applicable shape, such as a polygonal shape, for example a triangular or rectangular shape (including a square shape), or else of the shape of ‘a diamond. Preferably, the facets (F) are triangular in shape.

In the context of the present invention, the term “laser manufacturing process” is understood to mean any manufacturing process involving a laser to physically delimit a part. This process may involve, for example, cutting a part from a material sensitive to laser radiation, or the laser may heat a powder made from a material sensitive to said laser, thus causing the grains making up said powder to weld. In the latter case, it involves a powder, a process called “laser sintering”. Preferably, the “laser manufacturing process” in the context of the present invention is a laser sintering process. Examples of applications of such a method can be found in the literature such as documents U.S. Pat. No. 5,597,589, or more recently WO2018115767.

In the context of the present invention, the term “metal part” is understood to mean any part comprising at least one metal, for example in an alloy. Preferably, the part is completely metallic.

In the context of the present invention by “3D computer design”, it is understood that a spatial representation is carried out using a computer tool, such as a computer (fixed or portable), a touch pad, a notebook, a telephone. portable or even a fablet.

In the context of the present invention by “transfer of 3D data”, it is understood any means allowing the exchange of data generated by 3D computer design as defined above, from one computer tool to another. Preferably, the data transfer takes place from a computer tool dedicated to 3D design in a virtual manner to a computer tool dedicated to 3D manufacturing, i.e., connected to real product manufacturing tools, such as lasers, machining tools, etc. The means allowing the exchange of data generated by 3D computer design can be done via any suitable medium, such as a cable, a wireless network, a USB key, a CD-ROM, a DVD, etc.

In the context of the present invention by “3D laser manufacturing device”, it is understood a laser manufacturing device as defined above, dedicated to 3D manufacturing, that is to say using data generated by computer design. 3D, as defined above.

In the context of the present invention by “metal powder”, it is understood a substance consisting of metal particles, that is to say particles comprising at least one metal. A powder is characterized by its granulometry. Granulometry is the study of the statistical distribution of the sizes of a plurality of solid units (or pieces/granules) of natural or fractionated material (i.e., a collection). Particle size analysis is the set of operations making it possible to determine the size distribution of the elements making up a powder. The granulometry is the representation in the form of number tables or graphs of the experimental results of the particle size analysis. Metal powders which can be used for laser sintering typically have particles with a diameter of between 10 μm and 500 μm, for example between 20 μm and 100 μm, such as 50 μm±20 μm.

In the context of the present invention, “recovery” comprises any means making it possible to isolate an element from its environment. In this case, it may be a metal part formed by laser sintering in a metal powder used in its manufacture.

In the context of the present invention, the term “bag packaging” is understood to mean an outer packaging covering said bag. This packaging can be opaque and/or translucent. The packaging must be of a size larger than the bag it contains. This packaging can be made of a flexible and/or rigid material. The packaging may comprise or consist of an elastic material allowing it to adapt to the bag it is intended to contain. Preferably, the bag package according to the present invention is of similar exterior shape, if not identical to the exterior shape of the bag it contains.

### DETAILED DESCRIPTION

Bag and Bag Frame According to the Present Invention

The subject matter of the present invention therefore concerns a carrier bag frame, such as a handbag, as defined above. Preferably, the carrier bag frame according to the present invention comprises a basal part (B) and at least one side face (L), characterized in that said side face (L) is movably connected and/or fixed to said basal part (B). Preferably, said basal part (B) and at least one lateral face (L) are interconnected by at least one of their respective edges.

The subject matter of the present invention concerns more particularly a carrier bag frame as described here, characterized in that it comprises at least one part (PA) resulting from a 3D printing, an extrusion, a molding and/or a laser process, for example comprising at least one polymer, such as an organic polymer, and/or at least one metal, such as titanium, which metal is for example in the form of an alloy.

In a particular embodiment, the frame according to the present invention comprises at least one precious metal, for example chosen from the list consisting of gold, silver, platinum, rhodium, scandium, palladium, ruthenium, osmium and iridium, preferably gold, silver, and/or platinum.

The carrier bag frame according to the present invention can further be characterized in that the part (PA) is comprised in said basal part (B) and/or comprised in said side face (L).

In a particular embodiment, the frame of the carrier bag according to the present invention is characterized in that it comprises at least two basal parts (B) interconnected. For example, at least two basal parts (B) can be connected to each other by an axis of rotation inscribed in the plane of each basal part. The axis of rotation and therefore of attachment of the basal parts can be in any direction. Preferably, the axis of rotation and therefore of attachment of the basal parts is in the longitudinal direction of the bag, when the latter is of elongated shape.

The carrier bag frame according to the present invention can further be characterized in that said basal part (B) comprises several basal sub-parts of polygonal shape (s) each connected to each other by an axis of rotation, optionally with the aid of hinges, the axis or axes of rotation of the basal sub-parts preferably being oriented in the longitudinal direction of the bag, where appropriate. By “oriented in the longitudinal direction of the bag”, it is understood in the context of the present invention that the axes of rotation, which can be schematized by straight lines, are arranged parallel to the length of the bag

The carrier bag frame according to the present invention can further be characterized in that said basal part (B) is inscribed edge to edge in a rectangular parallelepiped of length (X), width (Y) and height (Z) whose plane defined by (X, Y) is the horizontal plane and the height (Z) is preferably of a dimension equal to or less than the largest dimension defined among the length X or the width Y.

The expression “edge-to-edge” should be understood in the context of the present invention as any protruding part such as an edge or a surface which can follow an edge or a surface of the rectangular parallelepiped of length (X), of width (Y) and height (Z) as defined above.

Thus, the longitudinal direction of the bag, (or even “length of the bag”) when the latter is elongated, can be easily determined as corresponding to the greatest value among X or Y. Preferably, the rigid lateral faces L are arranged. sequentially along the greatest value of X or Y, i.e., in the longitudinal direction; these side faces can be attached to the basal part (B) in a movable or fixed manner.

Preferably, the length (X) is less than or equal to one meter, less than or equal to fifty centimeters, less than or equal to thirty centimeters, less than or equal to twenty centimeters, less than or equal to ten centimeters.

Preferably, the width (Y) is less than or equal to one meter, less than or equal to fifty centimeters, less than or equal to thirty centimeters, less than or equal to twenty centimeters, less than or equal to ten centimeters.

Preferably, the height (Z) is less than or equal to one meter, less than or equal to fifty centimeters, less than or equal to thirty centimeters, less than or equal to twenty centimeters, less than or equal to ten centimeters.

Preferably, the length (X) and the width (Y) are independently of each other both less than or equal to one meter, both less than or equal to fifty centimeters, both less than or equal at thirty centimeters, both less than or equal to twenty centimeters, both less than or equal to ten centimeters.

The carrier bag frame according to the present invention can be characterized in that said basal part (B), and/or said lateral face (L), comprises at least one flat surface, at least one concave surface, at least a convex surface, and/or at least one twisted surface and in that said basal part (B), and/or said lateral face (L), is hollow (V) or solid

By “hollow”, it is understood that the side face is hollowed out, and that for example a fluid passes through said side face. The recessed part can be filled with a filling, for example a fabric.

The subject matter of the present invention concerns more particularly a carrier bag frame as described herein, characterized in that said basal part (B) comprises at least one surface of rectangular, triangular or square shape

In a particular embodiment, the carrier bag frame according to the present invention is characterized in that said basal part (B), and/or said lateral face (L), is corrugated.

More particularly, the carrier bag frame according to the present invention, can be characterized in that said lateral face (L) comprises a plurality of facets (F) attached to each other in a fixed and/or movable manner.

Advantageously, the carrier bag frame according to the present invention can be characterized in that:
a first lateral face (L1) is attached to a first edge (A1) of said basal part (B) and
a second lateral face (L2) is attached to a second edge (A2) of said basal part (B), the second edge (A2) preferably being an edge not adjacent to the first (A1).

In a particular embodiment, the frame of the carrier bag according to the present invention is characterized in that the first and/or the second lateral face (L1, L2) are not movable relative to the basal part (B).

More particularly, the carrier bag frame according to the present invention can be characterized in that the first and/or the second lateral face (L1, L2) are of generally polygonal shape, for example of square, rectangular, diamond shape, pentagonal or triangular, optionally wavy, twisted, convex, curved, and preferably adapted to be connected edge (s) to edge (s) with the base (B).

Thus, in a particular embodiment according to the present invention, the carrier bag frame as described herein, is characterized in that at least one side face (L) comprises at least one triangular flat surface (T), solid. or hollow (V).

The subject matter of the present invention also concerns a carrier bag frame as defined presently, characterized in that it is partially or fully lined with at least one fabric such as a woven or non-woven fabric, a knitted fabric or no, a natural or synthetic fabric, a fabric with or without a weaving weft, for example chosen from cotton, natural or synthetic leather, a polyester, polyamide, velvet, a polyacrylic, wool, neoprene, silk, cashmere, metal mesh, linen, Lyocell®, Galuchat®, etc.

By “lined”, it is understood in the context of the present invention that a fabric or a flexible material covers at least partially the frame.

The term “fabric” in the context of the present invention represents any type of flexible material that can be used to line a frame according to the definition above, or can be used in the manufacture of a carrier bag, such as a carrier bag. Hand. The flexible material that can be used in the context of the present invention may or may not be woven, natural or synthetic.

Thus, the subject matter of the present invention concerns a carrier bag, such as a handbag, characterized in that it comprises at least one frame as defined above.

The carrier bag, such as a handbag, according to the present invention may further comprise a closure means, for example magnetic, such as a series of magnets (A) placed on contact surfaces of a useful pocket of the bag. By “contact surface”, it is understood in the context at least two surfaces capable of touching each other.

Laser Manufacturing Method of a Metal Part for a Carrier Bag

The subject matter of the present invention further concerns a method for laser manufacturing a metal part which can be incorporated into a carrier bag, more particularly in a handbag, as defined above.

Thus, the subject matter of the present invention relates to a method of manufacturing a frame for a carrier bag, such as a handbag, as described above, characterized in that the frame is designed by computer, then at least one basal part (B), and/or at least one side face (L), is manufactured by 3D printing, extrusion, molding and/or is obtained from a laser process.

The computer design can be done by using suitable software, for example to generate a first polygonal surface, such as a triangle, and by a non-parallel translational movement (preferably perpendicular plus or minus 20°) to the plane of this surface, generated a volume which represents the bag/the frame according to the present invention. Preferably, the translational movement can vary in its axes in order to obtain a bag/frame with any possible variation in shape, for example with a twisted, convex, curved shape, etc. The translational movement may not vary, and a linear shape is thus obtained.

In a particular embodiment, the method according to the present invention is characterized in that the 3D printing involves a polymer and/or consists of a laser sintering process, for example on a metal alloy such as a titanium alloy.

The advantages of such a process are its ease of technical implementation. Thus, the design of the handbag is personalized according to the wishes of the customer directly on the computer tool which can also be accessible on a network (internet for example). The software which makes it possible to conceptualize the bag according to the present invention may further comprise a module for financial costing of the desired bag, depending on the materials and the desired structure. Thus, the client can directly see the financial cost of his virtual creation before its implementation with manufacturing tools, or even before its payment. The software can also benefit from tailor-made online help using a communication module with a technician and/or salesperson. The software can also be configured to limit the reinforcement thicknesses in order to obtain a product that can hold together and be sufficiently strong. Of course, all of these conceptualization steps can be done directly in a store with the help of someone who will help the customer with their design. The software can automatically generate the data needed to complete the packaging for the bag that has been defined by the customer. This packaging can be any flexible or rigid material. The packaging can be achieved by the same techniques as described for the frame of the bag itself (e.g., by sintering, 3D printing, laser cutting, etc.). Alternatively, the packaging can be made using flexible, more or less elastic materials in order to adapt to the bag made by the client.

### FIGURES

FIG. 1: This is an overview of different elements of the frame, which can be combined with specific shapes. The base (B) is here rectangular, slightly wavy. The two opposite triangular side faces (L1, L2) are positioned (fixed or mobile) on the shortest edges (A1, A2) of (B). These two opposite triangular lateral faces (L1, L2) can be made of a flexible or rigid material, possibly with at least one axis of rotation inscribed in their plane. The two opposing side faces (L3, L4) of rectangular shape are curved towards each other. The two opposite side faces (L3, L4) of curved rectangular shape are positioned (fixed or movable) on the longest edges (A3, A4) of (B). The two opposite side faces (L3, L4) fit the wavy shape of (B) and consist of a plurality of triangular facets (F) advantageously connected in a movable manner to each other (not shown, for example by a fabric), facilitating thus the opening of the useful pocket of the bag, once the latter has been made

FIG. 2: This is a plurality of example bases (B) according to the invention. The FIG. 2.1., FIG. 2.2. and FIG. 2.3. represent bases (B) of very slightly wavy rectangular shapes, solid (FIG. 2.1.) or hollowed out (cavities (V)) according to FIGS. 2.2. and 2.3. FIG. 2.2. represents a base (B) consisting of four rods connected to each other at the ends, thus forming a large cavity (V). FIG. 2.3. represents a base (B) comprising several cavities (V), here the cavities are rectangular in shape. The FIG. 2.4., FIG. 2.5. and FIG. 2.6. represent 3 solid bases with more marked undulations or twists than in the cases of FIG. 2.1, 2.2. or 2.3.

FIG. 3: This figure represents some examples of possible shapes of bags that can be obtained according to the present invention. The shape represented in FIG. 3.1. is characterized by a marked twist of the base (B). In contrast, the shape shown in FIG. 3.2. is characterized by a lack of torsion of the base (B), but which presents a domed shape. The form shown in FIGS. 3.3. and FIG. 3.4. are characterized by two opposite side faces (L1, L2) of different shapes. In FIG. 3.3., The opposite faces (L1, L2) are for one triangular and for the other oval. In FIG. 3.4., the opposite faces (L1, L2) are for one triangular and for the other rectangular. The bag of FIG. 3.4 is also characterized by the presence of a cover (C). In FIG. 3.5., The opposite faces (L1, L2) are hexagons.

FIG. 4: This figure represents a classic type handbag (with conventional fillings/covers) according to the present invention.

FIG. 5: This figure represents an embodiment of a handbag according to the invention. The general shape corresponds to FIG. 3.1. FIG. 5.1. represents the bag closed, whilst FIG. 5.2. represents the bag open, revealing the useful pocket (P). A series of magnets (A) enable to keep the bag closed. The side face (L1) is constituted of three moving parts (E1, E2, E3) one with each other; these parts can be rigid or flexible. The intersection of these three pieces defines an upside-down Y. It is the same for the opposite face (L2). The side faces (L3, L4) consist of a plurality of twisted and/or curved rectangles (R) fixed in a movable manner to the base (B), and in a movable manner with respect to each other (for example by the bias of a fabric placed/glued inside the useful pocket (P)).

FIG. 6: This figure represents another embodiment of a handbag according to the invention. The exterior shape is similar to the bag of FIG. 3.1. The embodiment according to FIG. 6 distinguishes itself by side faces (L1, L2) made of elastic fabric, by hollow frame elements and lined with fabric, and by its lateral faces (L3, L4) made up of a plurality triangular facets F hollowed out of their rigid material and lined with fabric, arranged “head to tail”. The triangular facets F are distributed in a movable manner relative to the base and can be movable to one another.

FIG. 7: This figure represents another embodiment of a handbag according to the invention. The exterior shape is similar to the bag of FIG. 6. The embodiment according to FIG. 7 distinguishes itself by several (two, here) basal parts (B) connected to each other by an axis of rotation inscribed in the plane of each basal part. The axis of rotation (and therefore of attachment of the basal sub-parts) is in the longitudinal direction of the bag, and the rigid lateral faces L are arranged sequentially in the longitudinal direction and attached in a fixed (or mobile, not shown) manner to the basal part (B)

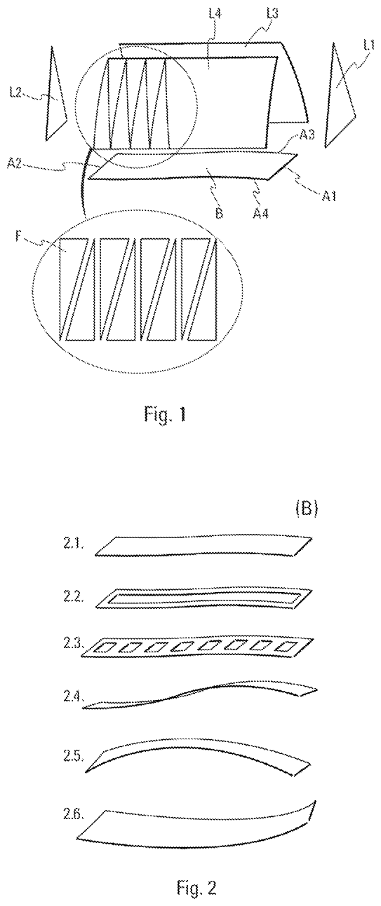

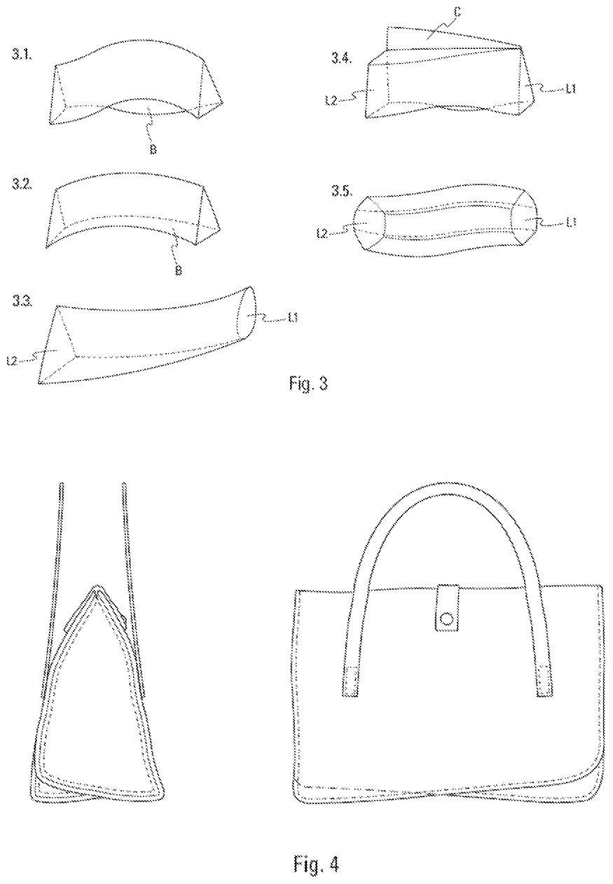

### EXAMPLES

### Example 1: Frame

Different materials have been used to make the frame according to the present invention.

The general shape of the frame is described in FIG. 6.

The plastic 3D printing process (A) used an EOSINT M280 machine with Nylon PA12 powder.

The laser method (B) (DLMS “Direct Metal Laser Sintering”) described used an EOSINT M280 machine with titanium powder TI64 or TiCP.

The molding process with plastic (C) referenced here by way of comparison concerns one of the classic molding methods using machined molds and conventional plastic polymers (polyethylenes, polypropylenes, epoxy polymers, polyesters, polyacrylates, polystyrenes, etc.).

TABLE 1
examples of reinforcements

| | | Positive | Negative |
|---|---|---|---|
| Frame | Material | points | points |
| A | 3D | Manufacturing cost | Shock and |
| | plastic printing | Malleable material | temperature |
| | | after manufacture | resistances, |
| | | (possible | Deformable |
| | | modifications after | material-short |
| | | production)) | lifespan |
| B | 3D printing by laser | Shock and | Manufacturing cost |
| | sintering of | temperature | |
| | titanium powder | resistance | |
| C* | Plastic moulding | Large scale | Cost of the mould, |
| | | manufacturing with | Shock and |
| | | pro-forma allowing | temperature |
| | | nevertheless | resistance |
| | | personalisation | Often deformable |
| | | | material-short |
| | | | lifespan |

* comparison by analogy

### Example 2: Bag Comprising a Frame According to the Invention

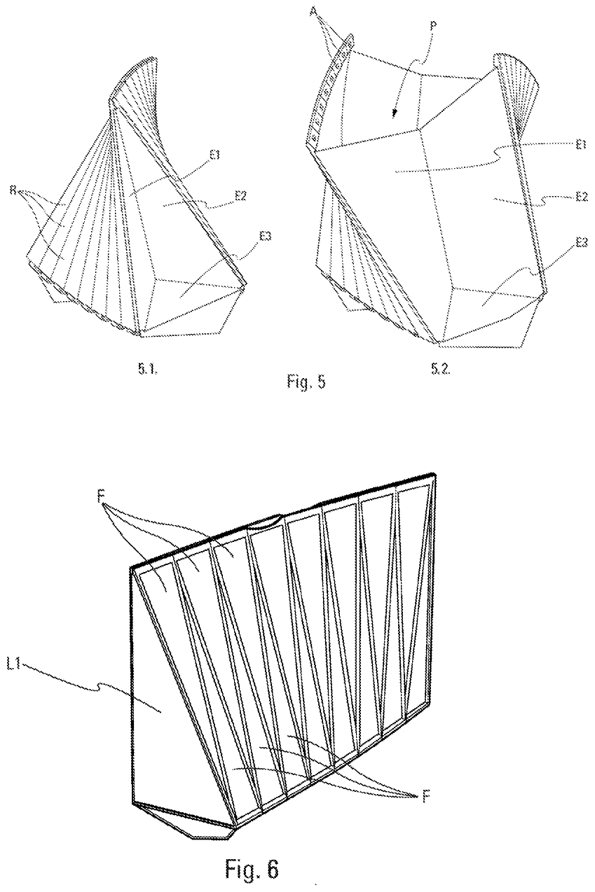

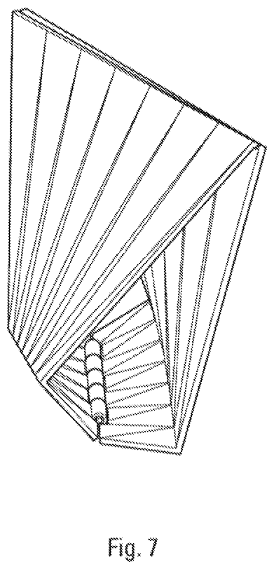

Handbags according to the invention were made according to FIG. 4, 5 or 6. The linings were placed on the frames using techniques customary in the art (by stitching with reinforcements discreetly glued to the areas of greatest wear). The frame can be more or less visible from the outside. For example, the handbag according to FIG. 4 does not show any frame which is fully lined (covered with fabric. In contrast, the embodiments according to FIGS. 5 and 6 clearly show the different elements of the frame.

1. Handbag comprising an integrated frame, wherein said frame comprises:
at least one rigid basal part (B) of polygonal shape, and/or
at least one lateral face (L1, L2, L3, L4) at least partly rigid, preferably attached in a fixed and/or movable manner to the basal part (B), where appropriate.

2. (canceled)

3. Handbag according to claim 1, characterized in that it comprises at least a part resulting from a 3D printing.

4. Handbag according to claim 1, characterized in that it comprises at least a part resulting from an extrusion.

5. Handbag according to claim 1, characterized in that it comprises at least a part resulting from a molding.

6. Handbag according to claim 1, characterized in that it comprises at least a part resulting from a laser process.

7. Handbag according to claim 3, characterized in that said part comprises at least one polymer.

8. Handbag according to claim 7, characterized in that the polymer is an organic polymer.

9. Handbag according to claim 3, characterized in that said part comprises at least one metal.

10. Handbag according to claim 9, characterized in that the metal is titanium.

11. Handbag according to claim 9, characterized in that the metal is in the form of an alloy.

12. Handbag according to claim 1, characterized in that said basal part (B) comprises several basal sub-parts of polygonal shape (s) each connected to one another by an axis of rotation.

13. Handbag according to claim 12, characterized in that said basal sub-parts of polygonal shape (s) are each connected to one another by means of hinges.

14. Handbag according to claim 12, characterized in that the axis or axes of rotation of the basal sub-parts are oriented in the longitudinal direction of the bag, where appropriate.

15. Handbag according to claim 1, characterized in that said basal part (B) is inscribed edge to edge in a rectangular parallelepiped of length (X), width (Y) and height (Z) whose plane defined by (X, Y) is the horizontal plane.

16. Handbag according to claim 15, characterized in that the height (Z) is of a dimension equal to or less than the largest dimension defined among the length (X) or the width (Y).

17. Handbag according to claim 1, characterized in that said basal part (B), and/or said lateral face (L1, L2, L3, L4), comprises at least one flat surface.

18. Handbag according to claim 1, characterized in that said basal part (B), and/or said lateral face (L1, L2, L3, L4), comprises at least one concave surface.

19. Handbag according to claim 1, characterized in that said basal part (B), and/or said lateral face (L1, L2, L3, L4), comprises at least one convex surface.

20. Handbag according claim 1, characterized in that said basal part (B), and/or said lateral face (L1, L2, L3, L4), comprises at least one twisted surface.

21. Handbag according to claim 1, characterized in that said basal part (B), and/or said lateral face (L1, L2, L3, L4), is hollow or solid.

22. Handbag according to claim 1, characterized in that said side face (L1, L2, L3, L4) comprises a plurality of facets (F) fixedly attached to each other.

23. Handbag according to claim 1, characterized in that said side face (L1, L2, L3, L4) comprises a plurality of facets (F) attached to each other in a movable manner.

24. Handbag according to claim 1, characterized in that:
a first lateral face (L1) is attached to a first edge (A1) of said basal part (B) and
a second lateral face (L2) is attached to a second edge (A2) of said basal part (B).

25. Handbag according to claim 24, characterized in that the second edge (A2) is an edge not adjacent to the first edge (A1).

26. A method of laser manufacturing a metal frame to be integrated into a handbag, according to claim 1, comprising the following steps:
(a) 3D computer design of said metal frame;
(b) transfer of the 3D data obtained in step (a) to a 3D laser manufacturing device;
(c) applying a laser of the device of step (b) to at least one metal; and
(d) recovery of the metal reinforcement thus obtained in step (c).

27. Manufacturing process according to claim 26, characterized in that the metal of step (c) comprises or consists of a metal powder.

28. Method of manufacturing a frame to be integrated into a handbag, according to claim 1, characterized in that the frame is designed by computer, then at least one basal part (B), and/or at least one side face (L1, L2, L3, L4), is manufactured by an industrial process.

29. Manufacturing process according to claim 28, characterized in that the industrial process comprises a step of 3D printing.

30. Manufacturing process according to claim 28, characterized in that the industrial process comprises an extrusion step.

31. Manufacturing process according to claim 28, characterized in that the industrial process comprises a molding step.

32. Manufacturing process according to claim 28, characterized in that the industrial process comprises a laser process step.

33.-34. (canceled)
